(19) United States
(12) Patent Application Publication
(10) Pub. No.: US 2025/0294751 A1
(43) Pub. Date: Sep. 18, 2025

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Masashi SHIMOMURA, Yokkaichi Mie (JP)

(73) Assignee: Kioxia Corporation, Tokyo (JP)

(21) Appl. No.: 18/975,235

(22) Filed: Dec. 10, 2024

(30) Foreign Application Priority Data
Mar. 18, 2024 (JP) 2024-042131

(51) Int. Cl. H10B 43/27; H10B 43/10

(52) U.S. Cl. CPC H10B 43/27; H10B 43/10

(57) ABSTRACT

A semiconductor memory device according to an embodiment, the device includes a first stacked body including a first stepped portion in which a plurality of first conductive layers are processed stepwise; a second stacked body disposed above the first stacked body, including a second stepped portion in which a plurality of second conductive layers are processed stepwise; a first insulating layer that covers the first and second stepped portions; a first layer that is interposed in the first insulating layer above the first stepped portion so as to be disposed at a height position between the first and second stacked bodies; and a first contact that extends downward from above the first stepped portion through the first insulating layer and the first layer and is connected to any one conductive layer of the plurality of first conductive layers processed stepwise.

### CROSS-REFERENCE TO RELATED APPLICATIONS

This application is based upon and claims the benefit of priority from Japanese Patent Application No. 2024-042131, filed on Mar. 18, 2024; the entire contents of which are incorporated herein by reference.

### FIELD

Embodiments described herein relate generally to a semiconductor memory device and a method for manufacturing the semiconductor memory device.

### BACKGROUND

In a semiconductor memory device such as a three-dimensional nonvolatile memory, memory cells are three-dimensionally arranged in a stacked body in which a plurality of conductive layers are stacked one by one while being separated from each other. These conductive layers are processed stepwise in a partial region of the stacked body, and a contact is connected to each of the conductive layers. When the contact is formed, the contact may come into contact with another configuration, and the electrical characteristics of the semiconductor memory device may deteriorate.

### BRIEF DESCRIPTION OF THE DRAWINGS

FIGS. 1A and 1B are diagrams illustrating a schematic configuration example of a semiconductor memory device according to an embodiment;

FIGS. 2A to 2D are sectional views illustrating an example of a configuration of the semiconductor memory device according to the embodiment;

FIGS. 3A to 3E are sectional views sequentially illustrating a part of procedure of a method for manufacturing the semiconductor memory device according to the embodiment;

FIGS. 4A to 4D are sectional views sequentially illustrating a part of procedure of a method for manufacturing the semiconductor memory device according to the embodiment;

FIGS. 5A to 5C are sectional views sequentially illustrating a part of procedure of a method for manufacturing the semiconductor memory device according to the embodiment;

FIGS. 6A to 6C are sectional views sequentially illustrating a part of procedure of a method for manufacturing the semiconductor memory device according to the embodiment;

FIGS. 7A to 7C are sectional views sequentially illustrating a part of procedure of a method for manufacturing the semiconductor memory device according to the embodiment;

FIGS. 8A to 8D are sectional views sequentially illustrating a part of procedure of a method for manufacturing the semiconductor memory device according to the embodiment;

FIGS. 9A to 9C are sectional views sequentially illustrating a part of procedure of a method for manufacturing the semiconductor memory device according to the embodiment;

FIGS. 10A to 10C are sectional views sequentially illustrating a part of procedure of a method for manufacturing the semiconductor memory device according to the embodiment;

FIGS. 11A to 11D are sectional views illustrating an example of a method for forming a contact hole according to an embodiment and a comparative example; and

FIGS. 12A and 12B are diagrams illustrating an example of a configuration of a semiconductor memory device according to a modification of the embodiment.

### DETAILED DESCRIPTION

A semiconductor memory device according to an embodiment, the device includes a first stacked body in which a plurality of first conductive layers are stacked apart from each other and including a first stepped portion in which the plurality of first conductive layers are processed stepwise; a second stacked body disposed above the first stacked body, in which a plurality of second conductive layers are stacked apart from each other and including a second stepped portion in which the plurality of second conductive layers are processed stepwise, the second stepped portion continuously extending from the first stepped portion; a first insulating layer that covers the first and second stepped portions; a first layer that contains a material different from a material of the first insulating layer and is interposed in the first insulating layer above the first stepped portion so as to be disposed at a height position between the first and second stacked bodies; and a first contact that extends downward from above the first stepped portion through the first insulating layer and the first layer and is connected to any one conductive layer of the plurality of first conductive layers processed stepwise.

Hereinafter, embodiments of the present invention will be described in detail with reference to the drawings. Note that the present invention is not limited by the following embodiments. In addition, constituent elements in the following embodiments include those that can be easily assumed by those skilled in the art or those that are substantially the same.

### (Configuration Example of Semiconductor Memory Device)

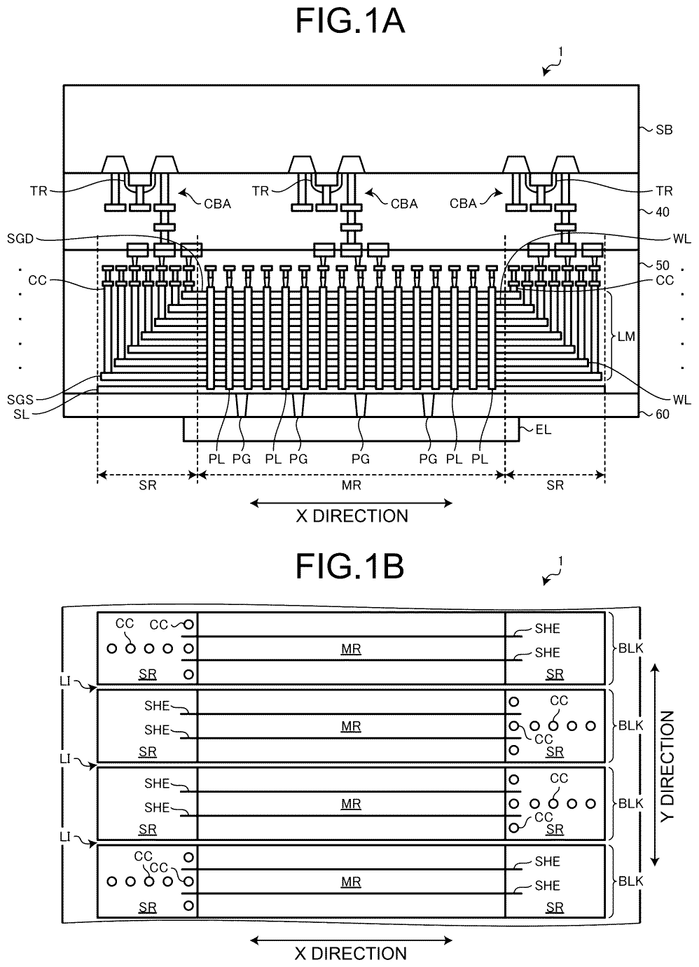

FIGS. 1A and 1B are diagrams illustrating a schematic configuration example of a semiconductor memory device 1 according to an embodiment. More specifically, FIG. 1A is a sectional view of the semiconductor memory device 1 along an X direction, and FIG. 1B is a schematic plan view illustrating a layout of the semiconductor memory device 1.

However, in FIG. 1A, hatching is omitted in consideration of visibility of the drawing. In addition, in FIG. 1A, configurations that do not necessarily exist in the same cross section are illustrated, and some upper layer wirings and the like are omitted.

In the present specification, both the X direction and a Y direction are directions along a direction of a surface of a word line WL, and the X direction and the Y direction are orthogonal to each other. In addition, an electrical drawing direction of the word line WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 1A, the semiconductor memory device 1 includes a semiconductor substrate SB on which an electrode film EL, a source line SL, one or more selection gate lines SGS, a plurality of word lines WL, one or more selection gate lines SGD, and a peripheral circuit CBA are provided in order from the lower side of the drawing.

The source line SL is disposed on the electrode film EL via an insulating layer 60. A plurality of plugs PG are disposed in the insulating layer 60, and the source line SL and the electrode film EL maintain electrical conduction via the plugs PG. Although not illustrated, an electrode pad for supplying power and a signal from the outside to the semiconductor memory device 1 is provided in the same layer as the electrode film EL. On the source line SL, the selection gate line SGS, the plurality of word lines WL, and the selection gate line SGD are stacked in this order to form a stacked body LM.

As illustrated in FIGS. 1A and 1B, a memory region MR is disposed at the center of the plurality of word lines WL in the X direction, and stepped regions SR are disposed at both end portions of the plurality of word lines WL in the X direction. The memory region MR and the stepped region SR are divided into a plurality of regions by a plurality of plate-like contacts LI extending in the direction along the X direction through the plurality of word lines WL and the like.

Note that a region disposed between the plate-like contacts LI adjacent in the Y direction and including the memory region MR and the stepped region SR is referred to as a block region BLK. As will be described later, the memory region MR includes a plurality of memory cells that hold data in a nonvolatile manner, and the block region BLK is an erase unit of the data.

Between the plate-like contacts LI adjacent in the Y direction, a plurality of separation layers SHE extending in the direction along the X direction through the selection gate line SGD is disposed. The plurality of separation layers SHE extend in the direction along the X direction over the entire memory region MR and reach a part of the stepped region SR at both end portions in the X direction.

In the memory region MR, a plurality of pillars PL penetrating the word line WL and the selection gate lines SGD and SGS in a stacking direction are arranged. A lower end of the pillar PL reaches the source line SL. A plurality of memory cells are formed at intersections of the pillars PL and the word lines WL. As a result, the semiconductor memory device 1 is configured as, for example, a three-dimensional nonvolatile memory in which the memory cells are three-dimensionally arranged in the memory region MR.

In the stepped region SR, the plurality of word lines WL and the selection gate lines SGD and SGS are processed stepwise and terminate. At this time, as the distance from the memory region MR increases in the X direction, the plurality of word lines WL and the selection gate lines SGD and SGS constituting a terrace portion shift from the upper layer side to the lower layer side, so that the height position of the terrace portion decreases toward the source line SL side.

Note that the separation layer SHE extends from the memory region MR to a portion where the selection gate line SGD of the stepped region SR is processed stepwise. As a result, in one block region BLK, the selection gate line SGD is separated into a plurality of regions. In other words, the separation layer SHE penetrates the portions above the plurality of word lines WL, so that these upper layer portions are partitioned into patterns of the plurality of selection gate lines SGD.

A contact CC connected to the word line WL and the selection gate lines SGD and SGS of each layer is arranged in a terrace portion of each stage including the plurality of word lines WL and the selection gate lines SGD and SGS. In the word line WL and the selection gate line SGS, one contact CC is connected for each layer. In the selection gate line SGD, one contact CC is connected for each section separated by the separation layer SHE per layer.

Here, in one block region BLK, the plurality of contacts CC are arranged on one side of the stepped regions SR on both sides in the X direction. When viewed on one side in the X direction, for example, a plurality of the contacts CC are arranged in every two of the block regions BLK.

That is, in the example of FIG. 1B, in the uppermost block region BLK in the drawing, a plurality of contacts CC are arranged, for example, in the stepped region SR on the left side in the drawing out of the stepped regions SR at both end portions in the X direction. In addition, in the block region BLK one below and two below the block region BLK, the plurality of contacts CC are arranged in the stepped region SR on the right side of the drawing out of the stepped regions SR at both end portions in the X direction. Furthermore, in the block region BLK at the lowermost portion in the drawing, the plurality of contacts CC are arranged again in the stepped region SR on the left side in the drawing.

Therefore, the contacts CC of the stepped regions SR at both end portions in the X direction illustrated in FIG. 1A belong to different block regions BLK, and are not actually located in the same cross section.

The word lines WL and the like stacked in multiple layers are individually drawn out by these contacts CC. More specifically, a write voltage, a read voltage, and the like are applied from these contacts CC to the memory cells included in the memory region MR at the central portions of the plurality of word lines WL via the word lines WL at the same height position as the memory cells.

The plurality of word lines WL, the selection gate lines SGD and SGS, the pillars PL, and the contact CC are covered with an insulating layer 50. The insulating layer 50 also extends around these configurations.

The semiconductor substrate SB above the insulating layer 50 is, for example, a silicon substrate or the like. A peripheral circuit CBA including a transistor TR, wiring, and the like is disposed on the surface of the semiconductor substrate SB. Various voltages applied from the contacts CC to the memory cells are controlled by peripheral circuits CBA electrically connected to the contacts CC. As a result, the peripheral circuit CBA controls the electrical operation of the memory cell.

The peripheral circuit CBA is covered with the insulating layer 40, and the insulating layer 40 and the insulating layer 50 covering the plurality of word lines WL and the like are bonded to form the semiconductor memory device 1 including the configurations of the plurality of word lines WL and the selection gate lines SGD and SGS, the pillars PL, the contacts CC, and the like, and the peripheral circuit CBA.

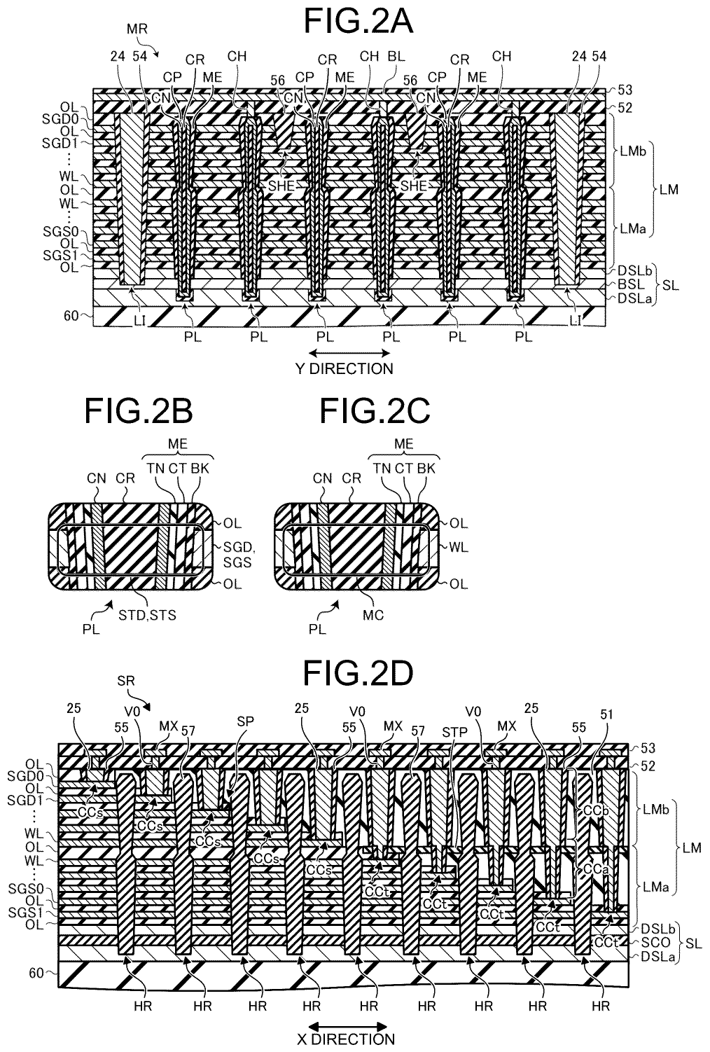

Next, a detailed configuration example of the semiconductor memory device 1 will be described with reference to FIGS. 2A to 2D. FIG. 2 is a sectional view illustrating an example of a configuration of the semiconductor memory device 1 according to the embodiment.

More specifically, FIG. 2A is a sectional view along the Y direction in the memory region MR of the semiconductor memory device 1. In FIG. 2A, structures below the insulating layer 60 and above an insulating layer 53 described later are omitted.

FIG. 2B is an enlarged sectional view of the pillar PL at the height positions of the selection gate lines SGD and SGS. FIG. 2C is an enlarged sectional view of the pillar PL at the height position of the word line WL.

FIG. 2D is a sectional view along the X direction in the stepped region SR of the semiconductor memory device 1. In FIG. 2D, structures below the insulating layer 60 and above the insulating layer 53 described later are omitted.

Note that, in the present specification, the direction in which a terrace surface of the word line WL of each step in the stepped region SR faces is defined as the upward direction in the semiconductor memory device 1.

As illustrated in FIG. 2A, the source line SL has a multilayer structure in which, for example, a lower source line DSLa, an intermediate source line BSL, and an upper source line DSLb are stacked in this order on insulating layer 60. The intermediate source line BSL is disposed below the memory region MR of the stacked body LM.

The lower source line DSLa, the intermediate source line BSL, and the upper source line DSLb are, for example, polysilicon layers. Among them, at least the intermediate source line BSL may be a conductive polysilicon layer or the like in which impurities are diffused.

The source line SL is connected to the peripheral circuit CBA via the electrode film EL by a through contact (not illustrated) extending from the electrode film EL to the peripheral circuit CBA in the insulating layer 50 outside the stacked body LM.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed above the source line SL. A plurality of selection gate lines SGS0 and SGS1 are arranged in this order from the upper layer side of the stacked body LMa via the insulating layer OL below the word line WL of the lowermost layer of the stacked body LMa. The stacked body LMb is disposed on the stacked body LMa. A plurality of selection gate lines SGD0 and SGD1 are arranged in this order from the upper layer side of the stacked body LMb via the insulating layer OL on the upper layer of the uppermost word line WL of the stacked body LMb.

However, the number of word lines WL and selection gate lines SGD and SGS stacked in the stacked body LM is optional. The word line WL and the selection gate lines SGD and SGS are, for example, a tungsten layer or a molybdenum layer. The insulating layer OL is, for example, a silicon oxide layer or the like.

The upper surface of the stacked body LM is covered with an insulating layer 52. The insulating layer 52 is covered with the insulating layer 53. The insulating layers 52 and 53 constitute a portion of an insulating layer 51 in FIG. 1A together with the insulating layer 50 described later.

As described above, the stacked body LM is divided in the Y direction by the plurality of plate-like contacts LI. That is, the plate-like contacts LI are arranged in the Y direction and extend in the stacking direction and the X direction of the stacked body LM.

As described above, the plate-like contact LI continuously extends in the stacked body LM from one end portion to the other end portion of the stacked body LM in the X direction. The plate-like contact LI penetrates the stacked body LM and the upper source line DSLb and reaches the intermediate source line BSL in the memory region MR.

In addition, the plate-like contact LI has, for example, a tapered shape in which a width in the Y direction decreases from an upper end portion toward a lower end portion. Alternatively, the plate-like contact LI has, for example, a bowing shape in which the width in the Y direction is maximized at a predetermined position between the upper end portion and the lower end portion.

Each of the plate-like contacts LI includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers the side walls of the plate-like contact LI facing each other in the Y direction. The conductive layer 24 is filled inside insulating layer 54, and electrically connected to the source line SL including the intermediate source line BSL. The upper end portion of the conductive layer 24 is connected to the upper layer wiring via a plug or the like at a position different from the cross section of FIG. 2A. Thus, the plate-like contact LI functions as a source line contact.

However, instead of the plate-like contact LI, the plate member filled with the insulating layer may penetrate the stacked body LM and extend in the direction along the X direction, thereby dividing the stacked body LM in the Y direction. In this case, the plate-like contact does not have a function as a source line contact.

Between the plate-like contacts LI adjacent in the Y direction, the plurality of separation layers SHE extending in the direction along the X direction through the upper layer portion of the stacked body LMb is disposed. These separation layers SHE are insulating layers 56 such as a silicon oxide layer that penetrate the selection gate lines SGD0 and SGD1 and reach the insulating layer OL immediately below the selection gate line SGD1.

In other words, these separation layers SHE penetrating the upper layer portion of the stacked body LMb extend between the plate-like contacts LI in the X direction between the memory region MR and a portion of the stepped region SR, so that the upper layer portion of the stacked body LMb is partitioned into the selection gate lines SGD0 and SGD1 described above.

In the memory region MR, a plurality of pillars PL penetrating the stacked body LM, the upper source line DSLb, and the intermediate source line BSL and reaching the lower source line DSLa are dispersedly arranged.

The plurality of pillars PL take, for example, a staggered arrangement when viewed from the stacking direction of the stacked body LM. Each pillar PL has, for example, a circular shape, an elliptical shape, an oval shape (oval shape), or the like as a sectional shape in a direction along the layer direction of the stacked body LM, that is, in a direction along an XY plane.

In addition, each of the pillars PL has a tapered shape in which the diameter and the sectional area decrease from the upper layer side toward the lower layer side in a portion penetrating the stacked body LMa and a portion penetrating the stacked body LMb. Alternatively, the pillar PL has a bowing shape in which the diameter and the sectional area are maximized at a predetermined position between the upper layer side and the lower layer side, for example, in a portion penetrating the stacked body LMa and a portion penetrating the stacked body LMb.

Each of the plurality of pillars PL includes a memory layer ME extending in the stacked body LM in the stacking direction, a channel layer CN penetrating the stacked body LM and connected to the intermediate source line BSL, a cap layer CP covering the upper surface of the channel layer CN, and a core layer CR serving as a core material of the pillar PL.

As illustrated in FIGS. 2B and 2C, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on the side surface of the pillar PL except for a depth position of the intermediate source line BSL. In addition, the memory layer ME is also disposed on a bottom surface of the pillar PL reaching the depth of the lower source line DSLa.

The channel layer CN penetrates the stacked body LM, the upper source line DSLb, and the intermediate source line BSL inside the memory layer ME, and reaches the depth of the lower source line DSLa. More specifically, the channel layer CN is disposed on the side surface and the bottom surface of the pillar PL via the memory layer ME. However, a part of channel layer CN is in contact with the intermediate source line BSL on the side surface, and is electrically connected to the source line SL including the intermediate source line BSL. The core layer CR is filled further inside the channel layer CN.

Each of the plurality of pillars PL has the cap layer CP at the upper end portion. The cap layer CP is disposed at the upper end portion of the pillar PL so as to cover at least the upper end portion of the channel layer CN, and is connected to the channel layer CN. In addition, the cap layer CP is connected to a bit line BL disposed in the insulating layer 52 via the plug CH disposed in the insulating layer 53. The bit line BL extends above the stacked body LM in the direction along the Y direction so as to intersect with the drawing direction of the word line WL.

In FIG. 2A, the plug CH is connected only to three pillars PL which penetrate the selection gate lines SGD separated into three of the six pillars PL and are electrically connected to the bit line BL illustrated in FIG. 2A. The other pillars PL are connected to another bit line BL extending in the direction along the Y direction in parallel with the bit line BL illustrated in FIG. 2A via the plug CH (not illustrated in FIG. 2A) at positions different from the cross section illustrated in FIG. 2A.

The block insulating layer BK and the tunnel insulating layer TN of the memory layer ME, and the core layer CR are, for example, silicon oxide layers or the like. The charge storage layer CT of the memory layer ME is, for example, a silicon nitride layer or the like. The channel layer CN and the cap layer CP are semiconductor layers such as a polysilicon layer or an amorphous silicon layer.

As illustrated in FIG. 2C, with the above configuration, the memory cells MC are formed in portions of the side surfaces of the pillars PL facing the individual word lines WL, respectively. When a predetermined voltage is applied from the word line WL, data is written to and read from the memory cell MC.

As illustrated in FIG. 2B, the selection gates STD are formed in portions where the side surfaces of the pillars PL face the selection gate lines SGD0 and SGD1 above the word lines WL, respectively. In addition, the selection gates STS are formed in portions where the side surfaces of the pillars PL face the selection gate lines SGS0 and SGS1 below the word lines WL, respectively.

When predetermined voltages are applied from the selection gate lines SGD and SGS, the selection gates STD and STS are turned on or off, and the memory cell MC of the pillar PL to which the selection gates STD and STS belong can be brought into a selected state or a non-selected state.

As illustrated in FIG. 2D, the stepped region SR has a stepped portion SP in which the plurality of word lines WL and the selection gate lines SGD and SGS are processed stepwise. The stepped portion SP illustrated in FIG. 2D is a portion in which the contact CC is disposed in the stepped region SR divided into the plurality of block regions BLK and having a drawing function of the word line WL and the like.

The stepped portion SP is covered with the insulating layer 51. The insulating layer 51 reaches, for example, the height position of the uppermost layer of the stacked body LM, and the insulating layers 52 and 53 also cover the upper surface of the insulating layer 51. As described above, the insulating layer 51 also constitutes a portion of the insulating layer 50 of FIG. 1A.

A stopper layer STP is disposed above a portion where the word line WL and the selection gate line SGS in the stacked body LMa of the stepped portion SP are processed stepwise. The stopper layer STP contains a material different from that of the insulating layer 51 and is interposed in the insulating layer 51 at a height position between the stacked bodies LMa and LMb. The insulating layer 51 is a silicon oxide layer or the like, whereas the stopper layer STP is, for example, a silicon nitride layer.

In the stepped region SR, instead of the intermediate source line BSL, the source line SL includes an intermediate insulating layer SCO interposed between the upper source line DSLb and the lower source line DSLa. The intermediate insulating layer SCO is, for example, a silicon oxide layer or the like.

Therefore, in the stepped region SR, the plate-like contact LI penetrates the insulating layer 51, the stacked body LM, and the upper source line DSLb and reaches the intermediate insulating layer SCO.

Each contact CC (CCs, CCt) penetrates the insulating layer 51 and the like and is connected to the word line WL or the selection gate lines SGD and SGS immediately below the insulating layer OL constituting each step of the stepped portion SP. Among a plurality of the contacts CCs and CCt, the contact CCs is a contact CC connected to any one of the plurality of word lines WL and the selection gate line SGD included in the stacked body LMb. On the other hand, the contact CCt is a contact CC connected to any one of the plurality of word lines WL and the selection gate line SGS included in the stacked body LMa.

Each of the contacts CCs has, for example, a tapered shape in which a diameter and a sectional area decrease from the upper end portion toward the lower end portion. Alternatively, the contact CC has, for example, a bowing shape with the largest diameter and sectional area at a predetermined position between the upper end portion and the lower end portion. In either case, the sectional area of the contact CCs continuously changes from the upper end portion to the lower end portion.

Each contact CCt penetrates the insulating layer 51 and the stopper layer STP interposed in the insulating layer 51, and reaches the word line WL or the selection gate line SGS immediately below the insulating layer OL constituting each step of the stepped portion SP. Each of contact CCt has a contact portion CCb which is an upper layer side portion of the stopper layer STP and a contact portion CCa which is a lower layer side portion of the stopper layer STP.

Each contact portion CCb has, for example, a tapered shape in which a diameter and a sectional area decrease from an upper end portion toward a lower end portion in contact with the stopper layer STP. Alternatively, the contact portion CCb has, for example, a bowing shape with the largest diameter and sectional area at a predetermined position between the upper end portion and the lower end portion. In either case, the sectional area of the contact portion CCb continuously changes from the upper end portion to the lower end portion.

Each contact portion CCa has, for example, a tapered shape in which a diameter and a sectional area decrease from the upper end portion in contact with the stopper layer STP toward the lower end portion in contact with the word line WL or the like to be connected. At this time, the sectional area of the contact portion CCa continuously changes from the upper end portion to the lower end portion.

In one contact CCt, the sectional area of the contact portion CCb along the XY plane is generally larger than the sectional area of the contact portion CCa along the XY plane. More specifically, the sectional area of the contact CCt changes discontinuously between the upper side and the lower side of the stopper layer STP, and the sectional area of the lower end portion of the contact portion CCb is larger than the sectional area of the upper end portion of the contact portion CCa.

When viewed from the stacking direction of the stacked bodies LMa and LMb, the central axis of the contact portion CCb may deviate from the central axis of the contact portion CCa. The reason why such a deviation occurs will be described later.

Hereinafter, these contacts CCs and CCt will be simply referred to as the contacts CC in a case where it is not particularly necessary to distinguish these contacts CCs and CCt.

The contact CC includes an insulating layer 55 covering the outer periphery of the contact CC and a conductive layer 25 such as a tungsten layer or a copper layer filling the inside of the insulating layer 55. The conductive layer 25 is connected to upper layer wiring MX disposed in the insulating layer 52 via a plug V0 arranged in the insulating layer 53. The upper layer wiring MX is electrically connected to the peripheral circuit CBA (refer to FIG. 1A).

With such a configuration, the word lines WL of the respective layers and the selection gate lines SGD and SGS of the upper and lower layers of the word lines WL can be electrically drawn from one end side or the other end side in the X direction of the stacked body LM. That is, with the above configuration, a predetermined voltage is applied from the peripheral circuit CBA to the memory cell MC via the upper layer wiring MX, the contact CC, the word line WL, and the like, and the memory cell MC can be operated as a memory element.

In the stepped region SR, a plurality of columnar portions HR is dispersedly arranged over the entire stepped region SR. As described later, these columnar portions HR have a role of supporting these configurations when forming the stacked body LM from the stacked body in which the sacrificial layer and the insulating layer are stacked, and do not contribute to the function of the semiconductor memory device 1.

In principle, the plurality of columnar portions HR are arranged in a grid shape or a zigzag shape when viewed from the stacking direction of the stacked body LM while avoiding interference with the plate-like contacts LI and the contacts CC. Each of the columnar portions HR has, for example, a circular shape, an elliptical shape, an oval shape, or the like as a sectional shape in a direction along the XY plane.

In addition, the columnar portion HR has a tapered shape in which the diameter and the sectional area decrease from the upper layer side toward the lower layer side in a portion penetrating the stacked body LMa and a portion penetrating the stacked body LMb. Alternatively, the columnar portion HR has a bowing shape in which the diameter and the sectional area are maximized at a predetermined position between the upper layer side and the lower layer side, for example, in a portion penetrating the stacked body LMa and a portion penetrating the stacked body LMb.

The entire columnar portion HR is a single body of an insulating layer 57 such as a silicon oxide layer. That is, the columnar portion HR is configured by the insulating layer 57 of substantially a single material. Here, the substantially single material can include a case where the element ratios of the constituent components of the columnar portions HR are different in one columnar portion HR or between a plurality of columnar portions HR, and a case where the type and amount of impurities contained are different, and it is allowable to include voids in the columnar portion HR of a single material.

Since the columnar portion HR is a single body of the insulating layer 57 as described above, the columnar portion HR cannot electrically affect other configurations, and interference with the adjacent plate-like contact LI or the like may be allowed within a predetermined range.

### (Method for Manufacturing Semiconductor Memory Device)

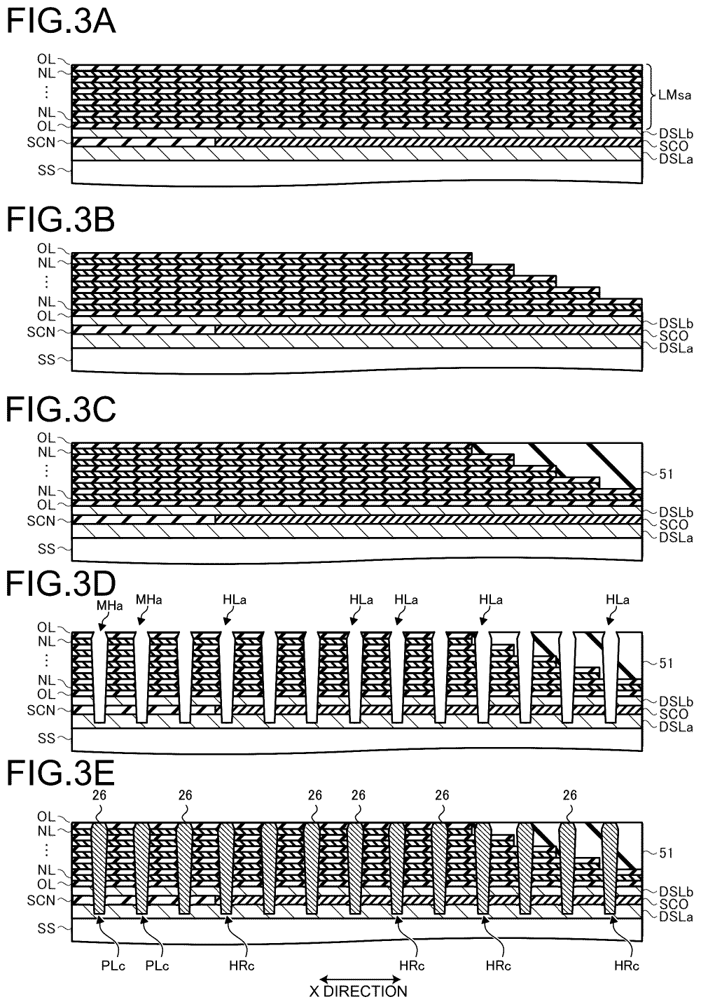

Next, a method for manufacturing the semiconductor memory device 1 according to the embodiment will be described with reference to FIGS. 3A to 10C. FIGS. 3A to 10C are diagrams sequentially illustrating a part of procedure of a method for manufacturing the semiconductor memory device 1 according to the embodiment.

First, FIGS. 3A to 3E illustrate a state in which various configurations are formed in a stacked body LMsa which is a lower layer portion of the stacked body LM before the word line WL is formed and the stacked body LMsa.

FIGS. 3A to 3E are sectional views along the X direction of regions to be the memory region MR and the stepped region SR later.

As illustrated in FIG. 3A, the lower source line DSLa, an intermediate sacrificial layer SCN or the intermediate insulating layer SCO, and the upper source line DSLb are formed in this order on a support substrate SS.

As the support substrate SS, a semiconductor substrate such as a silicon substrate, an insulating substrate such as a ceramic substrate, a conductive substrate, or the like can be used. The insulating layer 60 (refer to FIG. 2A and the like) described above may be formed on the upper surface side of the support substrate SS.

The intermediate sacrificial layer SCN is formed in a region on the support substrate SS to be the memory region MR later, and the intermediate insulating layer SCO is formed in a region on the support substrate SS to be the stepped region SR later. The intermediate sacrificial layer SCN is, for example, a silicon nitride layer or the like, and is a layer to be replaced with a polysilicon layer or the like later and become the intermediate source line BSL. As described above, the intermediate insulating layer SCO is, for example, a silicon oxide layer or the like.

In addition, the stacked body LMsa in which a plurality of insulating layers NL and a plurality of insulating layers OL are alternately stacked one by one is formed on the upper source line DSLb. The insulating layer NL is, for example, a silicon nitride layer or the like, and functions as a sacrificial layer that is later replaced with a conductive material and becomes the word line WL or the selection gate line SGS.

As illustrated in FIG. 3B, the insulating layer NL and the insulating layer OL are processed stepwise in a partial region of the stacked body LMsa. Such processing can be performed by repeating the slimming of a mask pattern such as a photoresist layer and the etching of the insulating layer NL and the insulating layer OL of the stacked body LMsa a plurality of times.

That is, the mask pattern is formed on the upper surface of the stacked body LMsa, and for example, the exposed insulating layer NL and the insulating layer OL are etched away one by one. In addition, by processing with oxygen plasma or the like, the end portion of the mask pattern is retracted to newly expose the upper surface of the stacked body LMsa, and the insulating layer NL and the insulating layer OL are further etched away one by one. By repeating such processing a plurality of times, a shape is formed stepwise.

As illustrated in FIG. 3C, the insulating layer 51 covering the stepped portion and reaching the height of the upper surface of the stacked body LMsa is formed. The insulating layer 51 is also formed in an outer region of the stacked body LMsa.

As illustrated in FIG. 3D, for example, a plurality of memory holes MHa and a plurality of holes HLa extending in the stacking direction of the stacked body LMsa are collectively formed. The memory hole MHa is a portion that later becomes a lower structure of the pillar PL. The hole HLa is a portion that later becomes a lower structure of the columnar portion HR.

The plurality of memory holes MHa are arranged in a region to be the memory region MR later, penetrate the stacked body LMsa, the upper source line DSLb, and the intermediate sacrificial layer SCN, and reach the lower source line DSLa. The plurality of holes HLa are arranged in a region to become the stepped region SR later, penetrate the insulating layer 51, the stacked body LMsa, the upper source line DSLb, and the intermediate insulating layer SCO, and reach the lower source line DSLa.

As illustrated in FIG. 3E, the memory holes MHa and HLa are filled with a sacrificial layer 26 such as an amorphous silicon layer or a CVD-carbon layer.

As a result, a pillar PLc in which the plurality of memory holes MHa is filled with the sacrificial layer 26 is formed in a region to be the memory region MR later. In addition, a columnar portion HRc in which the plurality of holes HLa are filled with the sacrificial layer 26 is formed in a region to be the stepped region SR later.

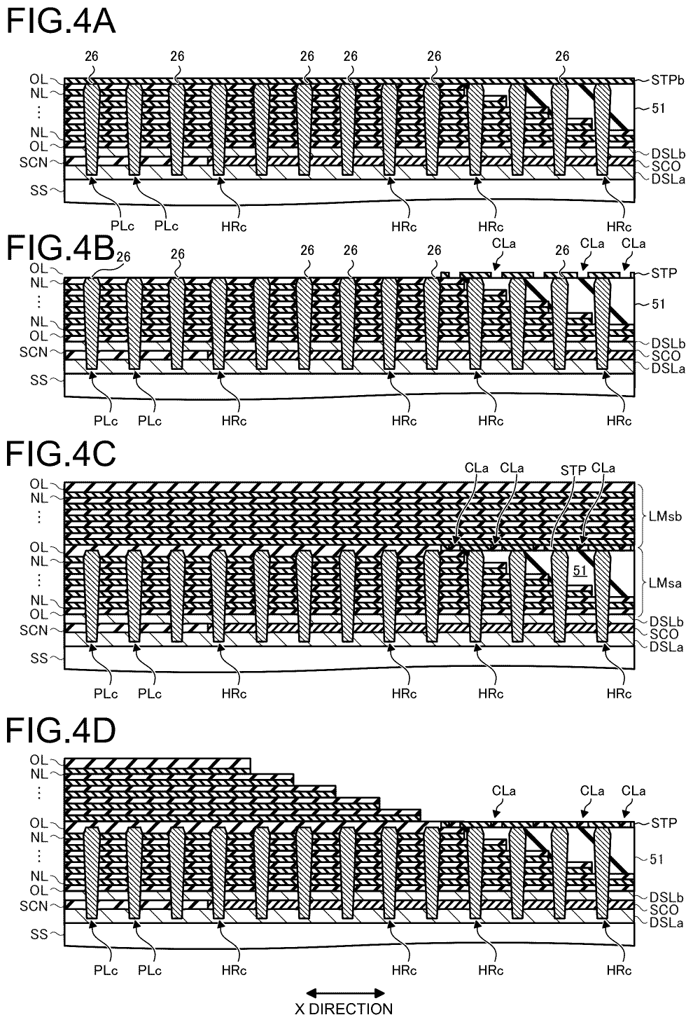

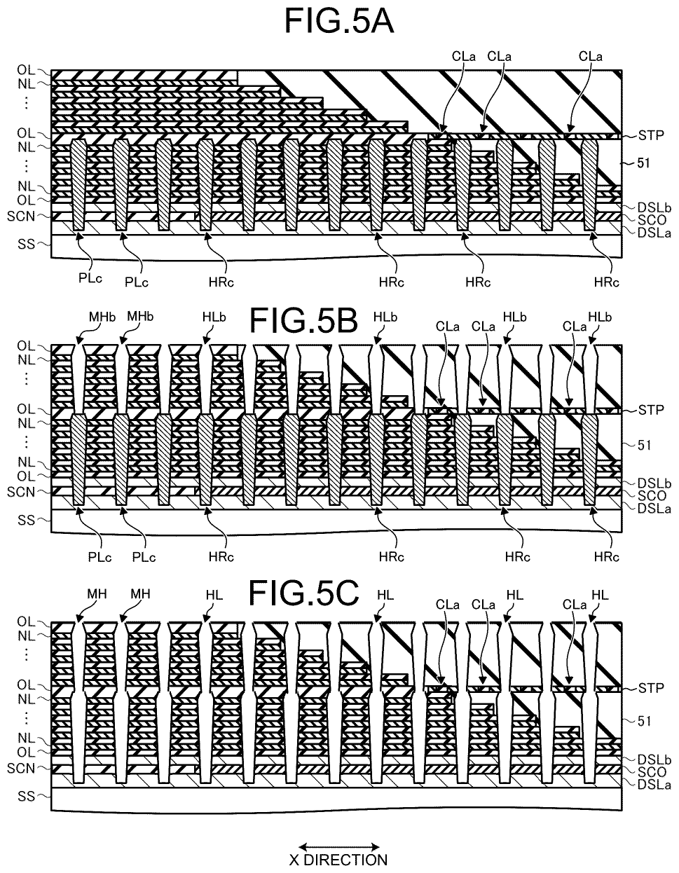

Next, FIGS. 4A to 5C illustrate a state in which a stacked body LMsb, which is an upper layer portion of the stacked body LM before the word line WL is formed, is partially formed with the stopper layer STP interposed therebetween, and various configurations are further formed in the stacked body LMsb.

FIGS. 4A to 5C are sectional views along the X direction of regions to be the memory region MR and the stepped region SR later, similarly to FIGS. 3A to 3E described above.

As illustrated in FIG. 4A, a stopper layer STPb that covers the top of the stacked body LMsa and the top of the insulating layer 51 in the stepped portion is formed. The stopper layer STPb is a layer that covers the entire surfaces of the stacked body LMsa and the insulating layer 51 before being formed in the pattern of FIG. 2D described above.

As illustrated in FIG. 4B, the stopper layer STPb is processed into the above-described pattern of the stopper layer STP. That is, in the portion covering the insulating layer 51, the portion covering the stacked body LMsa of the stopper layer STPb and the portion covering the insulating layer 51 are removed while leaving the portion where the plurality of contacts CCt are formed. In addition, a plurality of opening portions CLa are formed in the portion remaining on the insulating layer 51. These opening portions CLa are portions through which the contact CCt penetrates later. Further, when these opening portions CLa are formed, a mask pattern or the like aligned with the above-described columnar portion HRc is used.

More specifically, a mark (not illustrated) for aligning the mask pattern when the columnar portion HRc is formed is provided in any region on the support substrate SS. By forming the mask pattern having a pattern of the columnar portion HRc on the basis of this mark on the stacked body LMsa, the columnar portion HRc can be formed at a desired position of the stacked body LMsa using this mask pattern. By forming the mask pattern having a pattern of the opening portion CLa formed in the stopper layer STP with the same mark as a reference, the formation position of the opening portion CLa is aligned with respect to the columnar portion HRc.

As described above, by aligning the opening portion CLa with respect to the columnar portion HRc, the opening portion CLa can be formed while avoiding interference with the columnar portion HRC.

As described above, the stopper layer STP is formed on the insulating layer 51 covering the portion of the stacked body LMa processed stepwise.

As illustrated in FIG. 4C, the stacked body LMsa and the stopper layer STP in the stepped portion are covered, and the stacked body LMsb in which a plurality of insulating layers NL and a plurality of insulating layers OL are alternately stacked one by one is formed. At this time, the opening portion CLa provided in the stopper layer STP is filled with, for example, the insulating layer OL or the like. The sacrificial layer NL of the stacked body LMsb is later replaced with a conductive layer and becomes the word line WL or the selection gate line SGD.

As illustrated in FIG. 4D, the insulating layer NL and the insulating layer OL are processed stepwise in a partial region of the stacked body LMsb. Such processing can be performed by repeating the slimming of a mask pattern such as a photoresist layer and the etching of the insulating layer NL and the insulating layer OL of the stacked body LMsb a plurality of times, similarly to the processing illustrated in FIG. 3B described above.

At this time, the uppermost step of the stepped portion formed in the stacked body LMsa and the lowermost step of the stepped portion formed in the stacked body LMsb are brought close to each other, and are formed so as to be continuously connected from the lower layer side of the stacked body LMsa to the upper layer side of the stacked body LMsb. In addition, by removing the stacked body LMsb on the stepped portion of the stacked body LMsa, the stopper layer STP formed above the stepped portion of the stacked body LMsa is exposed again.

As illustrated in FIG. 5A, the insulating layer 51 covering the upper surface of the stopper layer STP exposed again and the stepped portion newly formed in the stacked body LMsb and reaching the height of the upper surface of the stacked body LMsb is formed. The insulating layer 51 is also formed in an outer region of the stacked bodies LMsa and LMsb. As a result, the insulating layer 51 in which the stopper layer STP is partially interposed is formed.

As illustrated in FIG. 5B, for example, a plurality of memory holes MHb and a plurality of holes HLb extending in the stacking direction at the height position of the stacked body LMsb are collectively formed. The memory hole MHb is a portion that becomes an upper structure of the pillar PL later. The hole HLb is a portion that later becomes an upper structure of the columnar portion HR.

The plurality of memory holes MHb is arranged in a region to be the memory region MR later, penetrates the stacked body LMsb, and reaches the upper end portions of the pillars PLC formed in the stacked body LMsa.

A part of the plurality of holes HLb is arranged at a position overlapping the stepped portion of the stacked bodies LMsa and LMsb in the stacking direction, penetrates the insulating layer 51 and the stacked body LMsb or the stopper layer STP, and reaches the upper end portion of the columnar portion HRc formed in the stacked body LMsa.

As illustrated in FIG. 5C, the sacrificial layer 26 is removed from the memory hole MHb, the pillar PLc at the bottom of the hole HLb, and the columnar portion HRc.

As a result, the memory holes MHa are opened at the bottoms of the plurality of memory holes MHb, and a plurality of memory holes MH penetrating the stacked bodies LMsb and LMsa, the upper source line DSLb, and the intermediate sacrificial layer SCN and reaching the lower source line DSLa are formed. In addition, the holes HLa open at the bottoms of the plurality of holes HLb, and a plurality of holes HL penetrating the insulating layer 51, the stacked body LMsb or the stopper layer STP, the stacked body LMsa, the upper source line DSLb, and the intermediate insulating layer SCO to reach the lower source line DSLa are formed.

Note that, in a case where the sacrificial layer 26 with which the pillars PLc and the columnar portions HRC are filled is a CVD-carbon layer or the like, when the mask pattern or the like used in the processing of FIG. 5B described above is removed by ashing or the like using oxygen plasma, the sacrificial layer 26 can also be collectively removed from the pillars PLc and the columnar portions HRC.

Thereafter, the insulating layer 57 is embedded in the hole HR formed in the region to be the stepped region SR later, and a plurality of columnar portions HR is formed.

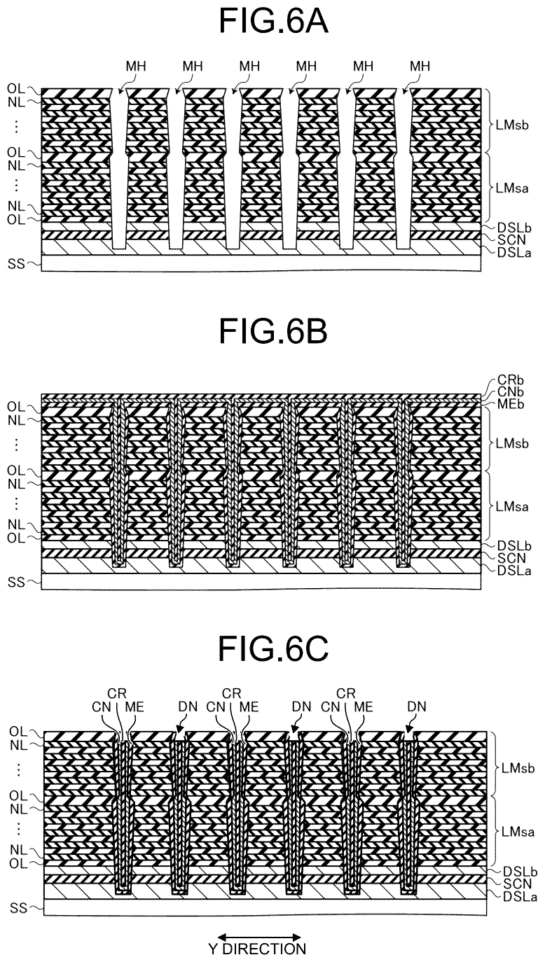

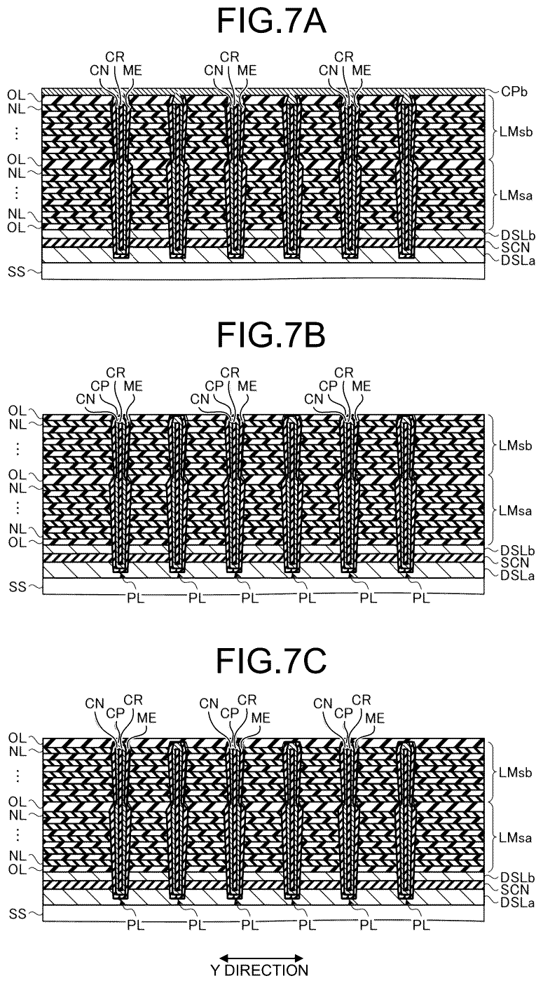

Next, a state in which the pillar PL is formed by forming a multilayer structure in the memory hole MH will be described with reference to FIGS. 6A to 7C. FIGS. 6A to 7C are sectional views along the Y direction of a region to be the memory region MR later.

As illustrated in FIG. 6A, a plurality of memory holes MH are formed in a region to be the memory region MR later.

As illustrated in FIG. 6B, a multilayer insulating layer MEb, a semiconductor layer CNb, and an insulating layer CRb are formed in this order in the memory hole MH. As a result, the multilayer insulating layer MEb and the semiconductor layer CNb are disposed on the side surface of the memory hole MH and the bottom surface where the lower source line DSLa is exposed, and the insulating layer CRb is filled in the central portion of the memory hole MH.

The multilayer insulating layer MEb is an insulating layer having a multilayer structure to be the memory layer ME later. The semiconductor layer CNb is a layer to be the channel layer CN later. The insulating layer CRb is a silicon oxide layer or the like that becomes the core layer CR later.

The multilayer insulating layer MEb, the semiconductor layer CNb, and the insulating layer CRb are also formed in this order on the upper surface of the stacked body LMsb.

As illustrated in FIG. 6C, in a region to be the memory region MR later, the insulating layer CRb, the semiconductor layer CNb, and the multilayer insulating layer MEb are sequentially etched back to be removed from the upper surface of the stacked body LMsb, and a recess DN from which the insulating layer CRb and the semiconductor layer CNb are removed is formed at the upper end portion of the memory hole MH.

As a result, the memory layer ME, the channel layer CN, and the core layer CR are formed in the memory hole MH in this order from the outer peripheral side.

As illustrated in FIG. 7A, a semiconductor layer CPb is formed in the recess DN at the upper end portion of the memory hole MH in a region to be the memory region MR later. The semiconductor layer CPb is a layer to be the cap layer CP later. The semiconductor layer CPb is also formed on the upper surface of the stacked body LMsb.

As illustrated in FIG. 7B, in a region to be the memory region MR later, the semiconductor layer CPb on the upper surface of the stacked body LMsb is removed by CMP or the like, and the cap layer CP is formed at the upper end portion of the memory hole MH. In addition, the uppermost insulating layer OL of the stacked body LMsb thinned by CMP or the like is stacked.

As a result, the pillar PL in which the cap layer CP is buried in the uppermost insulating layer OL is formed. However, at this point, the memory layer ME covers the entire side wall of the pillar PL, and a part of the side surface of the channel layer CN is not exposed from the memory layer ME.

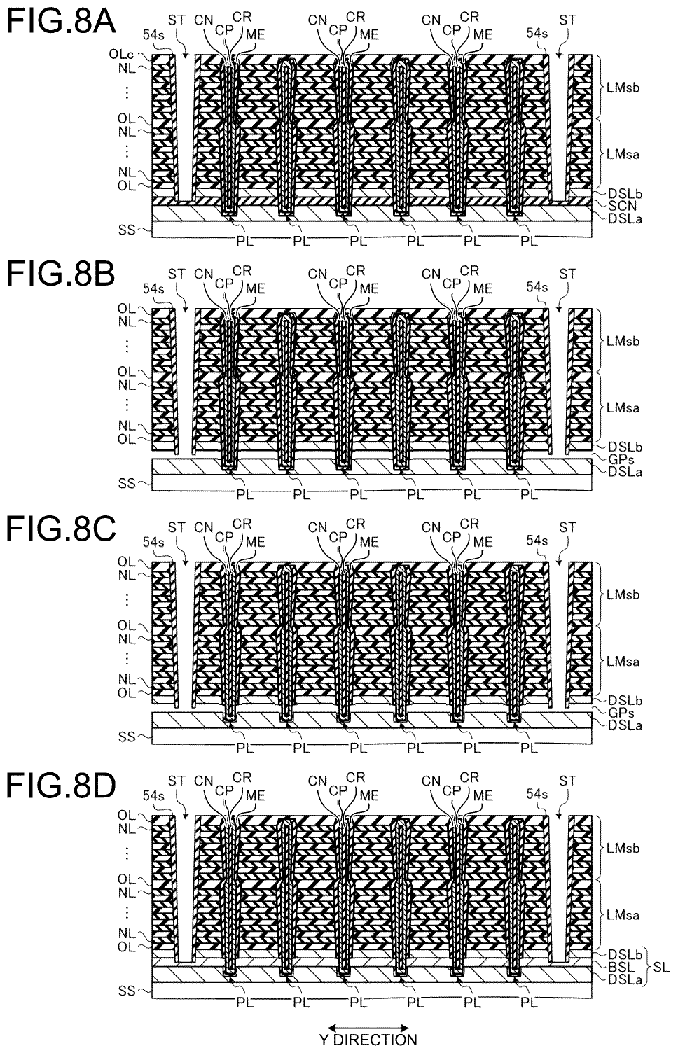

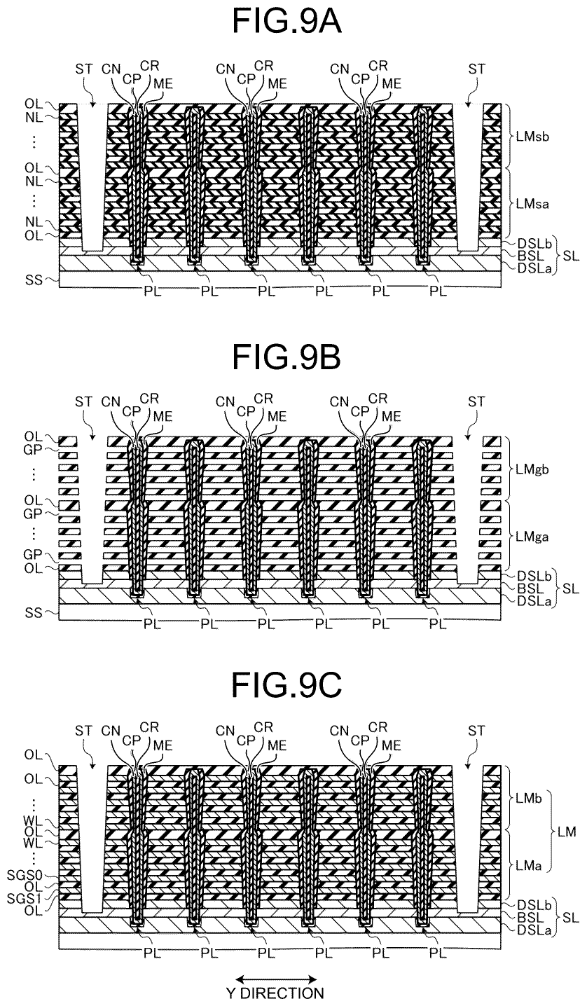

Next, a state in which the source line SL and the word line WL are formed will be described with reference to FIGS. 8A to 9C. FIGS. 8A to 9C are sectional views along the Y direction of a region to be the memory region MR later, similarly to FIG. 6A to FIG. 7C.

As illustrated in FIG. 8A, a slit ST that penetrates the stacked bodies LMsb and LMsa and the upper source line DSLb and reaches the intermediate sacrificial layer SCN is formed. Further, an insulating layer 54s is formed on the side walls of the slit ST facing each other in the Y direction.

The slit ST has a Y direction longitudinal cross section of a tapered shape or a bowing shape, and also extends in the stacked bodies LMsa and LMsb in the direction along the X direction. Therefore, in the stepped region SR (not illustrated), the lower end portion of the slit ST reaches the intermediate insulating layer SCO.

As illustrated in FIG. 8B, a removing liquid of the intermediate sacrificial layer SCN such as thermal phosphoric acid is caused to flow through the slit ST whose side wall is protected by the insulating layer 54s, and the intermediate sacrificial layer SCN sandwiched between the lower source line DSLa and the upper source line DSLb is removed.

As a result, a gap layer GPs is formed between the lower source line DSLa and the upper source line DSLb. Further, a part of the memory layer ME in the outer peripheral portion of the pillar PL is exposed in the gap layer GPs.

At this time, since the side wall of the slit ST is protected by the insulating layer 54s, it is suppressed that the insulating layer NL in the stacked bodies LMsa and LMsb is also removed. In addition, in the stepped region SR (not illustrated), there is no intermediate sacrificial layer SCN between the lower source line DSLa and the upper source line DSLb, and the gap layer GPs is not formed.

As illustrated in FIG. 8C, the chemical liquid is caused to appropriately flow into the gap layer GPs through the slit ST, and the block insulating layer BK, the charge storage layer CT, and the tunnel insulating layer TN (refer to FIGS. 2B and 2C) of the memory layer ME exposed in the gap layer GPs are sequentially removed. As a result, the memory layer ME is removed from a side wall of a part of the pillar PL, and a part of the channel layer CN on the inner side is exposed in the gap layer GPs.

As illustrated in FIG. 8D, a source gas such as amorphous silicon is injected from the slit ST whose side wall is protected by the insulating layer 54s, and the gap layer GPs is filled with amorphous silicon or the like. In addition, the support substrate SS is heat-treated to polycrystallize the amorphous silicon filled in the gap layer GPs, thereby forming the intermediate source line BSL containing polysilicon or the like.

As a result, a part of the channel layer CN of the pillar PL is connected to the source line SL on the side surface via the intermediate source line BSL.

At this time, in the stepped region SR (not illustrated), the gap layer GPs is not formed between the lower source line DSLa and the upper source line DSLb. In addition, the intermediate source line BSL is not formed.

As illustrated in FIG. 9A, the insulating layer 54s on the side wall of the slit ST is temporarily removed.

As illustrated in FIG. 9B, a removing liquid of the insulating layer NL such as, for example, hot phosphoric acid is caused to flow into the stacked bodies LMsa and LMsb from the slit ST to remove the insulating layers NL of the stacked bodies LMsa and LMsb. As a result, stacked bodies LMga and LMgb having the plurality of gap layers GP from which the insulating layers NL between the insulating layers OL are removed are formed.

The stacked bodies LMga and LMgb including the plurality of gap layers GP have a fragile structure. In a region to be the memory region MR later, the plurality of pillars PL support such fragile stacked bodies LMga and LMgb. On the other hand, in a region to be the stepped region SR later, the plurality of columnar portions HR support these stacked bodies LMga and LMgb.

Such a support structure of the pillars PL and the columnar portions HR suppresses bending of the remaining insulating layer OL and distortion or collapse of the stacked bodies LMga and LMgb.

As illustrated in FIG. 9C, a source gas of a conductive material such as tungsten or molybdenum is injected from the slit ST into the stacked bodies LMga and LMgb, and the gap layers GP of the stacked bodies LMga and LMgb are filled with the conductive material to form the plurality of word lines WL and the like. As a result, the stacked body LM including the stacked bodies LMa and LMb in which the plurality of word lines WL and the like and the plurality of insulating layers OL are alternately stacked one by one is formed.

The uppermost layer and the second conductive layer from the uppermost layer of the stacked body LMb are partitioned into a plurality of patterns of selection gate lines SGD by forming a separation layer SHE penetrating therethrough later.

As described above, the processing of forming the intermediate source line BSL from the intermediate sacrificial layer SCN and the processing of forming the word line WL from the insulating layer NL are also referred to as replacement processing.

As described above, the stopper layer STP is formed only in the region where the contact CCt is disposed. Therefore, for example, even the stopper layer STP, which is a silicon nitride layer or the like of the same type as the insulating layer NL, is suppressed from being replaced by the conductive layer by the replacement processing.

Thereafter, the insulating layer 54 is formed on the side wall of the slit ST, and the insulating layer 54 is filled with the conductive layer 24 to form the plate-like contact LI. However, the insulating layer 54 or the like may be filled in the slit ST without forming the conductive layer 24 to form a plate-like member.

In addition, a groove penetrating one or a plurality of conductive layers including the uppermost conductive layer of the stacked body LMb is formed, and the insulating layer 56 is filled in the groove, thereby forming the separation layer SHE that partitions these conductive layers into the pattern of the selection gate line SGD.

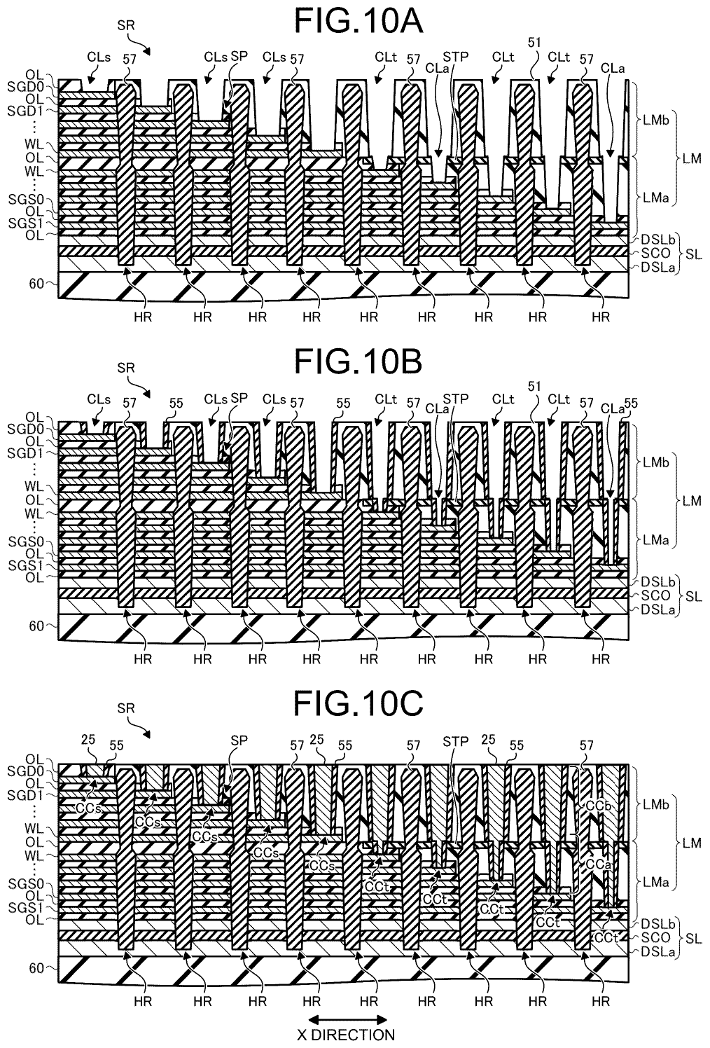

Next, a state in which a plurality of contacts CC is formed in the stepped region SR will be described with reference to FIGS. 10A to 10C. FIGS. 10A to 10C are sectional views of the stepped region SR along the X direction.

As illustrated in FIG. 10A, the plurality of columnar portions HR in which the insulating layer 57 is embedded in the hole HL is formed in the stepped region SR.

In addition, the plurality of contact holes CL (CLs, CLt) penetrating the insulating layer 51 and the like and respectively reaching the plurality of word lines WL and the selection gate lines SGD and SGS of the stacked bodies LMa and LMb are formed.

The plurality of contact holes CLs are formed so as to pass through the insulating layer 51 covering the portion where the plurality of word lines WL and the selection gate lines SGD of the stacked body LMb are processed stepwise, and to reach the word lines WL and the selection gate lines SGD, respectively.

The plurality of contact holes CLt are formed so as to pass through the insulating layer 51 covering the portion where the plurality of word lines WL and the selection gate lines SGS of the stacked body LMa are processed stepwise, and to reach the word lines WL and the selection gate lines SGS, respectively.

At this time, the opening portions of the contact holes CLt are formed, for example, to correspond to the formation positions of the opening portions CLa provided in the stopper layer STP and to be larger than the opening portions CLa. Etching conditions for forming the contact hole CL (CLs, CTt) are adjusted so as to have selectivity with respect to the stopper layer STP.

As a result, the insulating layer 51 such as a silicon oxide layer is selectively etched as compared with the stopper layer STP such as a silicon nitride layer. Then, the etching speed is extremely decreased or the etching is stopped in the portion reaching the stopper layer STP in the etching bottom surface of the contact hole CLt having the opening larger than the opening portion CLa of the stopper layer STP.

In addition, in a portion of the etching bottom surface of the contact hole CLt that has reached the opening portion CLa of the stopper layer STP, etching proceeds to below the stopper layer STP through the opening portion CLa, and can reach the word line WL or the like to be connected.

As a result, in the contact hole CLt, the sectional area along the XY plane on the lower side of the stopper layer STP is generally smaller than the sectional area along the XY plane on the upper side of the stopper layer STP. More specifically, the sectional area of the contact hole CLt discontinuously changes between the upper side and the lower side of the stopper layer STP, and the sectional area of the upper end portion of the lower side portion of the stopper layer STP is smaller than the sectional area of the lower end portion of the upper side portion of the stopper layer STP.

Note that each of the contact holes CLt is opened at a position corresponding to each of the opening portions CLa of the stopper layer STP, but a slight positional deviation may occur in the formation position of the contact hole CLt. In this case, the central axis of the contact hole CLt viewed from the stacking direction of the stacked bodies LMa and LMb is shifted between the upper side and the lower side of the stopper layer STP.

As illustrated in FIG. 10B, the insulating layer 55 is formed on the side wall of the contact hole CL.

As illustrated in FIG. 10C, the gap in the contact hole CL is filled with the conductive layer 25.

Thus, a plurality of contacts CC (CCs, CCt) are formed.

Thereafter, the insulating layer 52 is formed on the upper surface of the stacked body LM and the upper surface of the insulating layer 51 covering the stepped region SR, and the plug V0 connected to the contact CC is formed through the insulating layer 52. In addition, a plug CH connected to the pillar PL is formed through the insulating layer 52. Further, the insulating layer 53 is formed on the insulating layer 52, and the upper layer wiring MX, the bit line BL, and the like connected to the plugs V0 and CH are formed. In addition, an electrode pad or the like for electrically conducting with the peripheral circuit CBA is formed on the upper surface of the insulating layer 53.

For example, the plugs V0 and CH, the upper layer wiring MX, the bit line BL, and the like may be collectively formed by using a dual damascene method or the like.

In addition, the peripheral circuit CBA is formed on a semiconductor substrate SB separate from the support substrate SS on which the stacked body LM is formed, and is covered with the insulating layer 40. In the insulating layer 40, a contact, a via, wiring, or the like that leads the peripheral circuit CBA to the surface of the insulating layer 40 is formed and connected to an electrode pad or the like formed on the upper surface of the insulating layer 40.

Subsequently, the support substrate SS and the semiconductor substrate SB are bonded to each other by the insulating layers 50 and 40, respectively, and the electrode pads in the insulating layers 50 and 40 are connected. Thereafter, the support substrate SS is removed to expose the source line SL, and the electrode film EL is connected via the insulating layer 60 on which the plug PG is formed.

As described above, the semiconductor memory device 1 according to the embodiment is manufactured.

### Overview

A semiconductor memory device such as a three-dimensional nonvolatile memory is configured to be able to apply a voltage to a plurality of word lines or the like by stacking a plurality of word lines or the like, partially forming the word lines or the like stepwise, and connecting contacts to these stepped portions.

In addition, a stacked body in which a plurality of word lines and the like are stacked is formed, for example, by stacking a plurality of sacrificial layers and replacing them with a conductive material. When the sacrificial layer is replaced with the word line or the like, a columnar portion penetrating the stacked body may be formed in a stepped portion of the stacked body in order to support the stacked body having a fragile structure.

However, the columnar portion may be formed in an inclined manner due to stress generated between various components such as a stacked body or due to oblique incidence of ions during etching processing. Inclination due to oblique incidence of ions or the like during etching processing may also occur in the contact described above. Further, when the columnar portion and the contact are formed, positional deviation may occur in a mask pattern for processing the columnar portion and the contact. When at least one of the columnar portion and the contact is inclined or misaligned, the columnar portion and the contact may come into contact with each other.

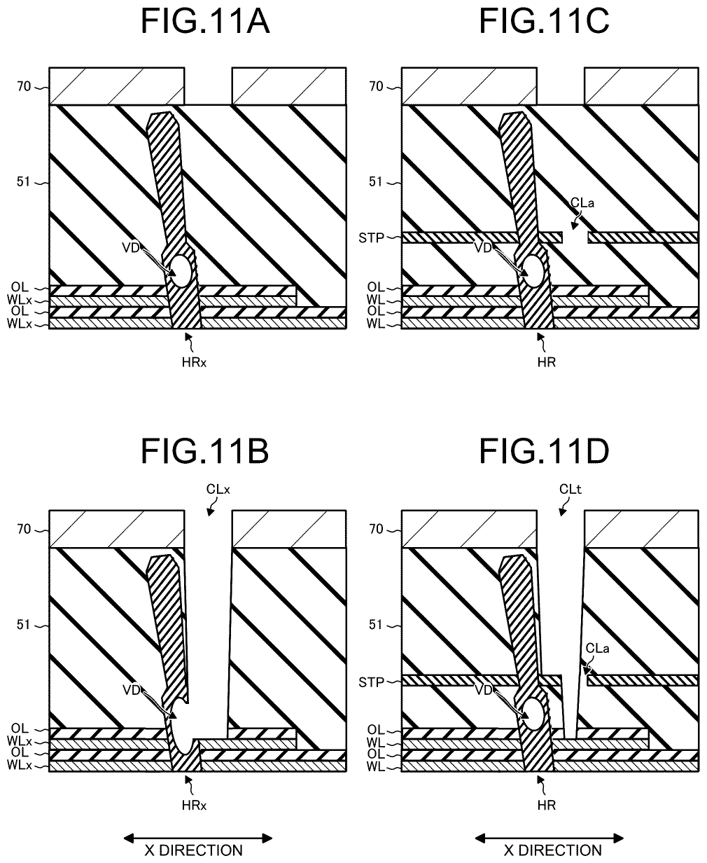

By using the method for manufacturing the semiconductor memory device 1 according to the embodiment, contact between the columnar portion HR and the contact CC can be suppressed. This point will be described with reference to FIGS. 11A to 11D.

FIGS. 11A to 11D are sectional views illustrating an example of a method for forming contact holes CLt and CLx according to an embodiment and a comparative example. As illustrated in FIGS. 11A to 11D, the contact holes CLt and CLx are formed using a mask pattern 70.

In the comparative example illustrated in FIG. 11A, it is assumed that inclination is generated in a columnar portion HRx. In addition, it is assumed that a void VD is generated in the columnar portion HRx when the insulating layer is embedded. In addition, it is assumed that a positional deviation occurs in the mask pattern 70 in a direction approaching the formed columnar portion HRX.

As illustrated in FIG. 11B, when the contact hole CLx of the comparative example is formed, for example, contact with the inclined columnar portion HRx occurs, and furthermore, the contact hole CLx communicates with the void VD in the columnar portion HRx, and etching may proceed to the lower side of the columnar portion HRx via the void VD.

When the contact hole CLx in such a state is filled with the conductive layer, the void VD extended downward is also filled with the conductive layer, and electrical leakage may occur between the adjacent lower word line WLx and the word line WLx to be connected with the contact.

Note that the contact between the contact hole CLx and the columnar portion HRx as described above is more likely to occur on the lower layer side of the stacked body. That is, contact is more likely to occur between the contact hole CLx to be connected to the word line WLx in the lower layer of the stacked body and the vicinity of the lower end portion of the columnar portion HRx arranged in the vicinity thereof.

Also in the example of the embodiment illustrated in FIG. 11C, it is assumed that the inclination is generated in the columnar portion HR, and the void VD is generated in the columnar portion HR when the insulating layer is embedded. In addition, it is assumed that the mask pattern 70 is displaced in a direction approaching the formed columnar portion HR. As a result, the opening of the mask pattern 70 that should overlap in the upper and lower directions and the opening portion CLa provided in the stopper layer STP do not completely overlap.

As illustrated in FIG. 11D, when the contact hole CLt of the embodiment is formed, a portion overlapping the inclined columnar portion HR in the upper and lower directions in the etching bottom surface of the contact hole CLt is located out of the opening portion CLa of the stopper layer STP. Therefore, the contact hole CLt reaches on the stopper layer STP, and etching is stopped there. As a result, the contact between the contact hole CLt and the columnar portion HR can be suppressed.

On the other hand, a portion of the etching bottom surface of the contact hole CLt overlapping the opening portion CLa in the upper and lower directions passes through the opening portion CLa as it is and reaches the word line WL to be connected. As a result, the contact CCt formed from the contact hole CLt can be more reliably connected to the word line WL to be connected.

Note that in a case where the inclination of the columnar portion HR is due to stress or the like generated in the stacked bodies LMga and LMgb or the like after the formation of the columnar portion HR, the stopper layer STP also receives similar stress. Therefore, the relative positional relationship between the opening portion CLa provided in the stopper layer STP and the columnar portion HR is maintained substantially as it is.

As described above, the opening portion CLa is aligned with the lower structure of the columnar portion HR and is formed so as to avoid interference with the lower structure of the columnar portion HR. Therefore, even when the inclination due to the stress occurs in the columnar portion HR, the contact hole CLt is formed through the opening portion CLa in which the relative positional relationship with the columnar portion HR is maintained, so that it is possible to further suppress the contact between the contact hole CLt and the columnar portion HR.

According to the semiconductor memory device 1 of the first embodiment, the contact CCt is provided which extends downward from above the stepped portion SP provided in the stacked body LMa through the insulating layer 51 and the stopper layer STP and is connected to any one of the plurality of word lines WL and the selection gate line SGS processed stepwise. As a result, contact between the contact CCt and other configurations can be suppressed.

In the above embodiment, the stopper layer STP is, for example, a silicon nitride layer. However, the stopper layer STP may be, for example, a polysilicon layer, an amorphous silicon layer, a metal oxide layer, or the like as long as the stopper layer STP contains a material different from that of the insulating layer 51 and is a layer having etching selectivity with respect to the insulating layer 51. The metal oxide layer may be, for example, an aluminum oxide (Al₂O₃) layer or the like.

In the above embodiment, the opening portion CLa of the stopper layer STP is smaller than the opening area of the contact hole CLt, for example. However, the opening portion CLa may be substantially equal to the opening area of the contact hole CLt, for example. In this case, in a state where there is no positional deviation with respect to the opening portion CLa, the diameter of the contact portions CCa and CCb of the contact CCt can be substantially equal.

However, the area of the opening portion CLa can be determined, for example, on the basis of the distance between the columnar portion HR and the contact CCt, and more preferably, on the basis of the distance between the lower end portions thereof, the size of the void VD that can occur in the columnar portion HR, and the like.

### (Modification)

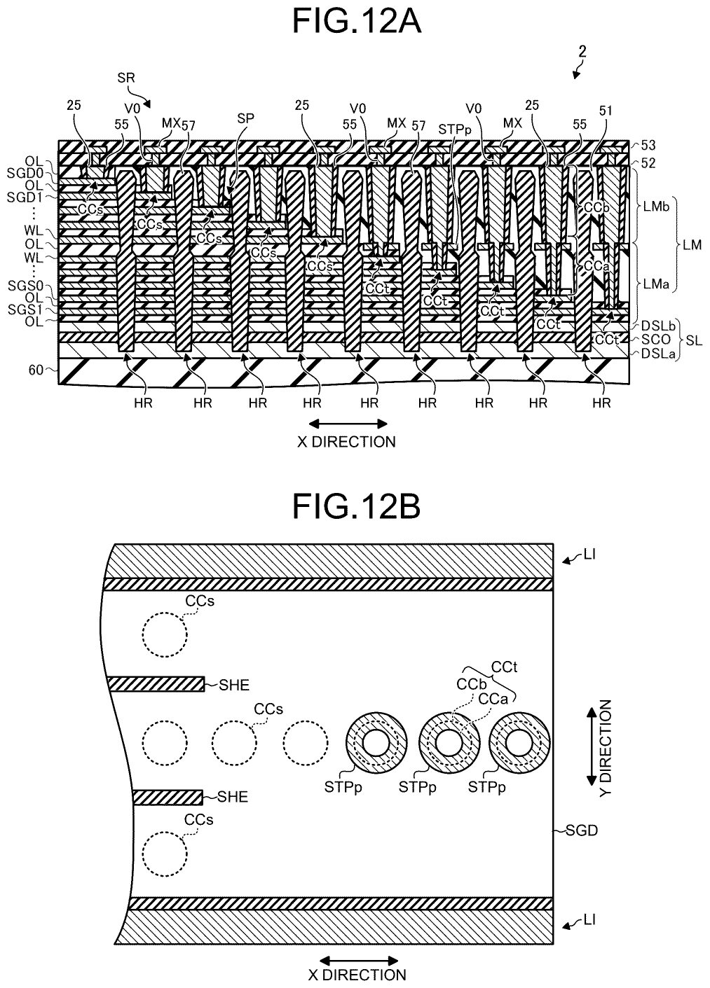

Next, a semiconductor memory device 2 according to a modification of the embodiment will be described with reference to FIGS. 12A and 12B. The semiconductor memory device 2 of the modification includes a stopper layer STPp made of a material different from the above-described stopper layer STP.

FIGS. 12A and 12B are diagrams illustrating an example of a configuration of the semiconductor memory device 2 according to the modification of the embodiment.

More specifically, FIG. 12A is a sectional view along the X direction in the stepped region SR of the semiconductor memory device 2. FIG. 12B is a sectional view along the XY plane at the height position of the selection gate line SGD in the stepped region SR of the semiconductor memory device 2. Note that, in FIG. 12A, structures below the insulating layer 60 and above the insulating layer 53 to be described later are omitted.

In FIGS. 12A and 12B, the same reference numerals are given to the same configurations as those of the above-described embodiment, and the description thereof may be omitted.

As illustrated in FIGS. 12A and 12B, the semiconductor memory device 2 of the modification includes the stopper layer STPp instead of the above-described stopper layer STP. The stopper layer STPp is, for example, a conductive layer such as a metal layer. As the metal layer, for example, a tungsten layer, a molybdenum layer, or the like can be used.

Since the stopper layer STPp is a conductive layer, in the semiconductor memory device 2 of the modification, the stopper layer STPp is provided separately for each contact CCt. Although the contact CCt has the insulating layer 55 on the side wall, it is possible to more reliably suppress the occurrence of conduction between the contacts CCt by separating the stopper layer STPp for each contact CCt.

As illustrated in FIG. 12B, the individually separated stopper layers STPp are formed to occupy at least an area larger than the cross section of the contact portion CCb which is the upper structure of the contact CCt. In FIG. 12B, a stopper layer STPp having a circular shape is illustrated as an example. However, the stopper layer STPp may have another shape such as a quadrangle or another polygon.

Such a stopper layer STPp is obtained, for example, by performing processing of separating for each of the plurality of contacts CCt in parallel at the time of forming the opening portion CLa illustrated in FIG. 4B of the above-described embodiment.

According to the semiconductor memory device 2 of the modification, the stopper layer STPp is dispersedly arranged at positions corresponding to the plurality of contacts CCt. Accordingly, even when the stopper layer STPp has conductivity, conduction between the contacts CCt can be suppressed.

According to the semiconductor memory device 2 of the modification, the stopper layer STPp contains at least one of tungsten and molybdenum as a main component. As described above, by using a metal material as the stopper layer STPp, the etching selectivity with respect to the insulating layer 51 which is, for example, a silicon oxide layer or the like can be further enhanced.

According to the semiconductor memory device 2 of the modification, other effects similar to those of the semiconductor memory device 1 of the above-described embodiment are obtained.

### (Other Modifications)

Note that, in the above-described embodiment and modification, the columnar portion HR is formed after forming a step structure, but the columnar portion HR may be formed before forming the step structure. In this case, when the step structure is formed, the columnar portion HR on the upper layer side partially disappears together with the stacked bodies LMsa and LMsb processed stepwise. Even in this case, since the columnar portion HR on the lower layer side remains, the risk of contact with the contact CCt can be suppressed by applying the above configuration.

In the embodiment and the modification described above, in the method of drawing out the plurality of word lines WL and the like on one side, contacts are alternately arranged in the Y direction every two block regions BLK in the stepped region SR on one side in the X direction. However, in the one-side drawing-out system such as the word line WL, the contacts may be arranged on one side in the X direction in the same block region BLK, and the arrangement order is not limited to the above.

In the embodiment and the modification described above, the stacked body LM having a two-tier structure in which two stacked bodies LMa and LMb are stacked on top of each other is provided. However, the configuration of the stacked body is not limited to two tiers, and may be three tiers or more.

Further, in the above-described embodiment and modification, the pillar PL is connected to the source line SL on the side surface of the channel layer CN, but the present invention is not limited thereto. For example, the pillar may be configured to be connected to the source line at the lower end portion of the channel layer by removing the memory layer on the bottom surface of the pillar.

In the above-described embodiment and modification, the peripheral circuit CBA is disposed above the stacked body LM. However, the peripheral circuit may be disposed below the stacked body or in the same layer as the stacked body.

In a case where the peripheral circuit is disposed below the stacked body, for example, the source line and the stacked body can be formed on an insulating layer of a semiconductor substrate having the peripheral circuit covered with the insulating layer. When the peripheral circuit is disposed on the same layer as the stacked body, the stacked body can be formed at a position different from the peripheral circuit on the semiconductor substrate on which the peripheral circuit is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first stacked body in which a plurality of first conductive layers are stacked apart from each other and including a first stepped portion in which the plurality of first conductive layers are processed stepwise;
a second stacked body disposed above the first stacked body, in which a plurality of second conductive layers are stacked apart from each other and including a second stepped portion in which the plurality of second conductive layers are processed stepwise, the second stepped portion continuously extending from the first stepped portion;
a first insulating layer that covers the first and second stepped portions;
a first layer that contains a material different from a material of the first insulating layer and is interposed in the first insulating layer above the first stepped portion so as to be disposed at a height position between the first and second stacked bodies; and
a first contact that extends downward from above the first stepped portion through the first insulating layer and the first layer and is connected to any one conductive layer of the plurality of first conductive layers processed stepwise.

2. The semiconductor memory device according to claim 1, wherein
a sectional area of the first contact viewed from a stacking direction of the first and second stacked bodies discontinuously changes between an upper side and a lower side of the first layer.

3. The semiconductor memory device according to claim 2, wherein
the sectional area of the first contact viewed from the stacking direction at a height position of an upper surface of the first layer is larger than the sectional area of the first contact viewed from the stacking direction at a height position of a lower surface of the first layer.

4. The semiconductor memory device according to claim 1, wherein
a central axis of the first contact viewed from a stacking direction of the first and second stacked bodies is shifted between an upper side and a lower side of the first layer.

5. The semiconductor memory device according to claim 2, further comprising:
a second contact that extends downward from above the second stepped portion through the first insulating layer and is connected to any one conductive layer of the plurality of second conductive layers processed stepwise, wherein
a sectional area of the second contact viewed from the stacking direction continuously changes from an upper end portion to a lower end portion.

6. The semiconductor memory device according to claim 1, further comprising:
a plurality of third contacts that extend downward from above the first stepped portion through the first insulating layer and the first layer, and are connected to each of the plurality of first conductive layers processed stepwise, the plurality of third contacts including the first contact.

7. The semiconductor memory device according to claim 6, wherein
the first layer continuously extends over an entire region where the plurality of third contacts are arranged.

8. The semiconductor memory device according to claim 7, wherein
the first insulating layer contains silicon oxide as a main component, and
the first layer contains, as a main component, at least one of selected from the group consisting silicon nitride, silicon, and a metal oxide.

9. The semiconductor memory device according to claim 6, wherein
the first layer is dispersedly disposed at each corresponding position of the plurality of third contacts.

10. The semiconductor memory device according to claim 9, wherein
the first insulating layer contains silicon oxide as a main component, and
the first layer contains, as a main component, at least one of selected from the group consisting tungsten, molybdenum, and a combination thereof.

11. A method for manufacturing a semiconductor memory device, the method comprising:
forming a first stacked body in which a plurality of first sacrificial layers are stacked apart from each other, and including a first stepped portion in which the plurality of first sacrificial layers are processed stepwise;
covering the first stepped portion with a first insulating layer;
forming a first layer containing a material different from a material of the first insulating layer on the first insulating layer;
above the first stacked body, forming a second stacked body in which a plurality of second sacrificial layers are stacked apart from each other and a second stepped portion is included, the second stepped portion, in which the plurality of second sacrificial layers are processed stepwise, continuously extending from the first stepped portion;
additionally forming the first insulating layer to further cover the second stepped portion and the first layer;
forming a plurality of first conductive layers included in the first stacked body and a plurality of second conductive layers included in the second stacked body by replacing the plurality of first and second sacrificial layers with a conductive material; and
forming a first contact extending downward from above the first stepped portion through the first insulating layer and the first layer and connected to any one conductive layer of the plurality of first conductive layers processed stepwise, wherein
the first layer is formed by including an opening portion in a portion through which the first contact penetrates, and
the first contact is formed by penetrating the first insulating layer through the opening portion so as that the first contact extends in upper and lower directions of the first layer.

12. The method for manufacturing a semiconductor memory device according to claim 11, wherein
the first contact is formed such that a sectional area of the first contact viewed from a stacking direction of the first and second stacked bodies is larger than an area of the opening portion viewed from the stacking direction on an upper side of the first layer.

13. The method for manufacturing a semiconductor memory device according to claim 11, wherein
the forming the first contact includes:
forming, in parallel, a second contact that extends downward from above the second stepped portion through the first insulating layer and is connected to any one conductive layer of the plurality of second conductive layers processed stepwise.

14. The method for manufacturing a semiconductor memory device according to claim 11, wherein
the forming the first contact includes:
including the first contact, forming a plurality of third contacts that extend downward from above the first stepped portion through the first insulating layer and the first layer and are connected to each of the plurality of first conductive layers processed stepwise.

15. The method for manufacturing a semiconductor memory device according to claim 14, wherein
when the opening portion is formed in the first layer,
the opening portion is formed in a portion through which the plurality of third contacts will be penetrate.

16. The method for manufacturing a semiconductor memory device according to claim 14, wherein
the first layer is formed to continuously extend over an entire region in which the plurality of third contacts are arranged.

17. The method for manufacturing a semiconductor memory device according to claim 16, wherein
the first insulating layer contains silicon oxide as a main component, and
the first layer contains, as a main component, at least one of selected from the group consisting silicon nitride, silicon, and a metal oxide.

18. The method for manufacturing a semiconductor memory device according to claim 14, wherein
the first layer is dispersedly formed at each corresponding position of the plurality of third contacts.

19. The method for manufacturing a semiconductor memory device according to claim 18, wherein
the first insulating layer contains silicon oxide as a main component, and
the first layer contains, as a main component, at least one of selected from the group consisting tungsten, molybdenum, and a combination thereof.

20. The method for manufacturing a semiconductor memory device according to claim 11, the method further comprising:
forming a columnar portion extending at a height position of the first stacked body in the first stepped portion, wherein
the opening portion is formed so as to be aligned with the columnar portion.
